(19) United States
(12) Patent Application Publication
(10) Pub. No.: US 2023/0002888 A1
(43) Pub. Date: Jan. 5, 2023

(54) METHOD OF DEPOSITING METAL FILMS

(71) Applicant: Applied Materials, Inc., Santa Clara, CA (US)

(72) Inventors: Feng Q. Liu, San Jose, CA (US); Mark Saly, Santa Clara, CA (US); David Thompson, San Jose, CA (US)

(73) Assignee: Applied Materials, Inc., Santa Clara, CA (US)

(21) Appl. No.: 17/365,919

(22) Filed: Jul. 1, 2021

(51) Int. Cl. C23C 16/18; C23C 16/50; C23C 16/455

(52) U.S. Cl. CPC C23C 16/18; C23C 16/50; C23C 16/45536; C23C 16/45553

(57) ABSTRACT

Methods of depositing high purity metal films are discussed. Some embodiments utilize a method comprising exposing a substrate surface to an organometallic precursor comprising a metal selected from the group consisting of molybdenum (Mo), tungsten (W), osmium (Os), rhenium (Re), iridium (Ir), nickel (Ni) and ruthenium (Ru) and an iodine-containing reactant comprising a species having a formula RIₓ, where R is one or more of a C₀-C₁₀ alkyl, cycloalkyl, alkenyl, or alkynyl group and x is in a range of 1 to 4 to form a carbon-less iodine-containing metal film; and exposing the carbon-less iodine-containing metal film to a reductant to form a metal film. Some embodiments deposit a metal film with greater than or equal to 90% metal species on an atomic basis.

### TECHNICAL FIELD

Embodiments of the disclosure generally relate to methods for depositing metal films. More particularly, embodiments of the disclosure are directed to methods for depositing high purity metal films having low oxygen content and low carbon content.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a precursor, a purge gas, a reactant and the purge gas. The precursor and the reactant react to form a product compound as a film on the substrate surface. The cycle is repeated to form the layer to a desired thickness. Some cycles expose the substrate surface to a precursor, a purge gas, a reactant, and the purge gas, and expose the film having the product compound to a reductant to form a deposited film (e.g., a metal film).

The advancing complexity of advanced microelectronic devices is placing stringent demands on currently used deposition techniques. Unfortunately, there is a limited number of viable chemical precursors available that have the requisite properties of robust thermal stability, high reactivity, and vapor pressure suitable for film growth to occur. In addition, precursors that often meet these requirements, e.g., organometallic precursors, lead to deposition reactions that produce metal-carbon bonds that are difficult to reduce. Current processes include oxidizing metal-carbon bonds to form metal-oxygen bonds to deposit a metal film. Metal-oxygen bonds are also difficult to reduce to deposit a metal film. Halogen-containing reactants, for example, convert the metal-carbon bonds to metal-halogen bonds. It is believed that metal-halogen bonds are more easily reduced than metal-carbon bonds and metal-oxygen bonds to deposit the metal film.

There is, therefore, a need in the art for reductants to enable selective deposition of high purity metal films.

### SUMMARY

One or more embodiments of the disclosure are directed to a method of depositing a film comprising exposing a substrate surface to an organometallic precursor and an iodine-containing reactant to form a carbon-less iodine-containing metal film.

Additional embodiments of the disclosure are directed to methods of depositing a film comprising exposing a substrate surface to an organometallic precursor comprising a metal selected from the group consisting of molybdenum (Mo), tungsten (W), osmium (Os), rhenium (Re), iridium (Ir), nickel (Ni) and ruthenium (Ru) and an iodine-containing reactant comprising a species having a formula RIₓ, where R is one or more of a C₀-C₁₀ alkyl, cycloalkyl, alkenyl, or alkynyl group and x is in a range of 1 to 4 to form a carbon-less iodine-containing metal film; and exposing the carbon-less iodine-containing metal film to a reductant to form a metal film.

Further embodiments of the disclosure are directed to a method of depositing a film comprising exposing a substrate surface to an organometallic precursor comprising molybdenum (Mo) and an iodine-containing reactant comprising diiodomethane (CH₂I₂) to form a carbon-less iodine-containing metal film; and exposing the carbon-less iodine-containing metal film to a reductant comprising hydrogen (H₂) to form a metal film, wherein the metal film comprises greater than or equal to 90% metal species on an atomic basis, and wherein the metal film has a resistivity less than or equal to 100 μΩ-cm.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method in accordance with one or more embodiments of the disclosure; and

FIG. 2 illustrates a process flow diagram of a method in accordance with one or more embodiment of the disclosure.

### DETAILED DESCRIPTION

Before describing several exemplary embodiments of the disclosure, it is to be understood that the disclosure is not limited to the details of construction or process routines set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate”, “substrate surface”, or the like, as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the transition metal-containing layer, for example, by polishing, etching, reduction, oxidation, halogenation, hydroxylation, annealing, baking, or the like.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate such that the transition metal-containing layer may be at least partially formed thereon. For example, in some embodiments, a layer comprising a metal, a nitride, an oxide, or the like, or combinations thereof may be disposed on the substrate and may have the transition metal-containing layer formed upon such layer or layers.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

According to one or more embodiments, the method uses an atomic layer deposition (ALD) process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness. In some embodiments, there may be two reactants, A and B, that are alternatingly pulsed and purged. In other embodiments, there may be three or more reactants, A, B, and C, that are alternatingly pulsed and purged.

In an embodiment of a spatial ALD process, a first reactive gas and second reactive gas (e.g., metal precursor gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

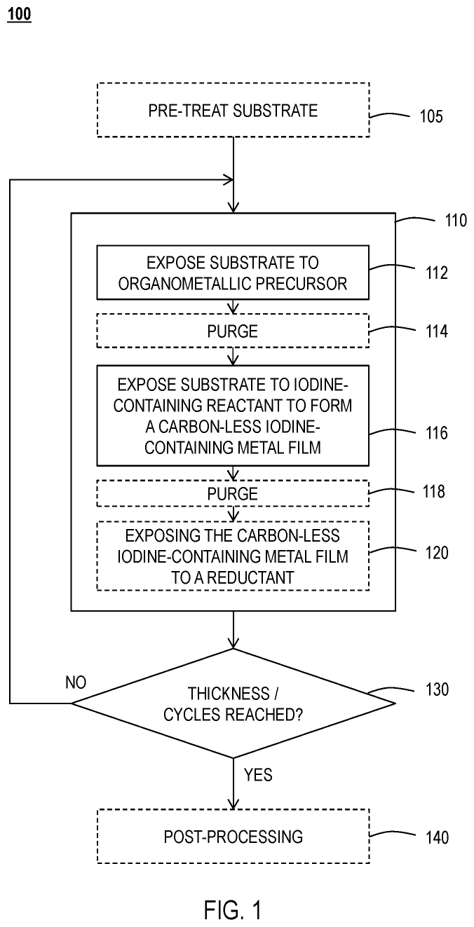

With reference to FIG. 1, one or more embodiments of the disclosure are directed to a method 100 of depositing a film. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the thin film.

In some embodiments, the method 100 optionally includes a pre-treatment operation 105. The pre-treatment can be any suitable pre-treatment known to the skilled artisan. Suitable pre-treatments include, but are not limited to, pre-heating, cleaning, soaking, native oxide removal, or deposition of an adhesion layer (e.g., titanium nitride (TiN)). In one or more embodiments, an adhesion layer, such as titanium nitride, is deposited at operation 105. In other embodiments, an adhesion layer is not deposited.

In one or more embodiments, operation 105 includes a pre-treatment hydrogen anneal process. In one or more embodiments, the pre-treatment hydrogen anneal process occurs under a set of process conditions. In one or more embodiments, the set of process conditions include heat, pressure, and carrier gas. In one or more embodiments, the pre-treatment hydrogen anneal process comprises heating to a temperature in a range of from 70° C. to about 450° C. In one or more embodiments, the pre-treatment hydrogen anneal process comprises a pressure in a range of from 0.5 Torr to about 20 Torr. In one or more embodiments, the pre-treatment hydrogen anneal process comprises flowing in a range of from 100 sccm to 20000 sccm of hydrogen.

At deposition 110, a process is performed to deposit a metal film on the substrate (or substrate surface). The deposition process can include one or more operations to form a film on the substrate. In one or more embodiments, the process is conducted at a temperature in a range of from 150° C. to 500° C. In one or more embodiments, the process is conducted at a pressure in the range of 0.1 Torr to 10 Torr, or at a pressure of at least 0.8 Torr.

At operation 112, the substrate (or substrate surface) is exposed to an organometallic precursor to deposit a film on the substrate (or substrate surface). The organometallic precursor can be any suitable organometallic compound that can react with (i.e., adsorb or chemisorb onto) the substrate surface to leave a metal species on the substrate surface.

In one or more embodiments, the organometallic precursor comprises a metal selected from the group consisting of molybdenum (Mo), tungsten (W), osmium (Os), rhenium (Re), iridium (Ir), nickel (Ni) and ruthenium (Ru).

In one or more embodiments, the organometallic precursor comprises molybdenum (Mo). In one or more embodiments, the organometallic precursor comprising molybdenum (Mo) comprises a precursor selected from the group consisting of bis(ethylbenzene)Mo, bis(benzene)Mo, bis(methylbenzene)Mo, (Bicyclo[2.2.1]hepta-2,5-diene)tetracarbonylmolybdenum(0), Cycloheptatriene molybdenum tricarbonyl, (ethylcyclopentadienyl)Mo(NMe₂)₃, (methylcyclopentadienyl)Mo(NMe₂)₃ tBuDADMo(CO)₄, bis(t-butylimido) bis(dimethylamino)Mo, Bis(ethylcyclopentadienyl)Mo dihydride, Mo₁₄, CpMo(CO)₂(NO), and MeCpMo(Co)₂(NO).

In one or more embodiments, the organometallic precursor comprises metal-carbon bonds. In one or more embodiments, the organometallic precursor comprises Mo—C bonds, W—C bonds, Os—C bonds, Re—C bonds, Ir—C bonds, Ni—C bonds, or Ru—C bonds.

At operation 114, the processing chamber is optionally purged to remove unreacted organometallic precursor, reaction products and by-products. As used in this manner, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of the precursor by any suitable technique including, but not limited to, moving the substrate through a gas curtain to a portion or sector of the processing chamber that contains none or substantially none of the organometallic precursor. In one or more embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), and argon (Ar). In one or more embodiments, operation 114 comprises flowing at least 200 sccm of the purge gas. In one or more embodiments, the substrate surface is purged of the organometallic precursor prior to exposing the substrate to a reactant.

At operation 116, the substrate (or substrate surface) is exposed to an iodine-containing reactant to form a carbon-less iodine-containing metal film on the substrate. The iodine-containing reactant can react with the organometallic species on the substrate surface to form the carbon-less iodine-containing metal film.

In one or more embodiments, the iodine-containing reactant comprises a species having a formula RIₓ, where R is one or more of a C₀-C₁₀ alkyl, cycloalkyl, alkenyl, or alkynyl group and x is in a range of 1 to 4. In one or more embodiments, R comprises one or more of a methyl, ethyl, n-propyl, isopropyl, n-butyl, s-butyl, t-butyl, n-pentyl, s-pentyl, t-pentyl, hexyl, or a cyclohexyl group. In one or more embodiments, I is monoiodo (I) or diiodo (I₂). In one or more embodiments, the iodine-containing reactant comprises diiodomethane (CH₂I₂).

In one or more embodiments, at operation 116, exposing the substrate (or substrate surface) to the iodine-containing reactant forms a carbon-less iodine-containing metal film on the substrate. In one or more embodiments, exposing the substrate (or substrate surface) to the iodine-containing reactant converts metal-carbon bonds to metal-iodine bonds. In one or more embodiments, exposing the substrate (or substrate surface) to the iodine-containing reactant forms Mo—I bonds, W—I bonds, Os—I bonds, Re—I bonds, Ir—I bonds, Ni—I bonds, or Ru—I bonds.

At operation 118, the processing chamber is optionally purged after exposure to the iodine-containing reactant. Purging the processing chamber in operation 118 can be the same process or different process than the purge in operation 114. Purging the processing chamber, portion of the processing chamber, area adjacent the substrate surface, etc., removes unreacted reactant, reaction products and by-products from the area adjacent the substrate surface.

The period of time of each operation in deposition 110 can be varied in order to form a deposited film (e.g., the metal film) of a predetermined thickness. In one or more embodiments, at operation 112, the method 100 comprises exposing the substrate (or substrate surface) to an organometallic precursor for 1 second. In one or more embodiments, at operation 114, the method 100 optionally includes purging the substrate for 2 seconds. In one or more embodiments, at operation 116, the method 100 comprises exposing the substrate to the iodine-containing reactant for a time in the range of 0.1 second to 5 seconds. In one or more embodiments, at operation 118, the method 100 optionally includes purging the substrate for a time in the range of 0.1 to 10 seconds.

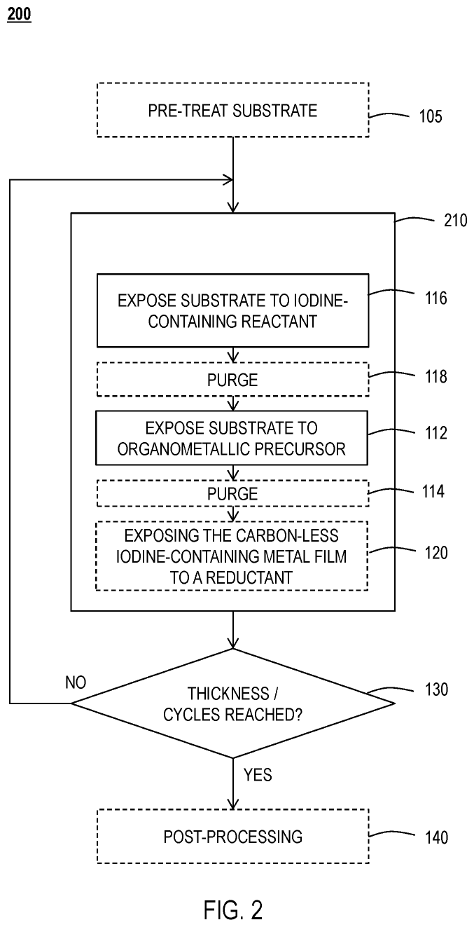

FIG. 2 shows an alternate embodiment of a method 200 in which the substrate is exposed to the iodine-containing reactant at operation 116 prior to exposure to the organometallic precursor at operation 112. The embodiment illustrated shows the operations 116, 118 occurring prior to operations 112, 114. In the embodiment of FIG. 2, without being bound by any particular theory of operation, it is believed that in operation 210 exposing the substrate to the iodine-containing reactant prior to exposure to the organometallic precursor helps prevent carbon contamination from the underlying films. In some embodiments, operation 210 further comprises exposing the substrate to the iodine-containing reactant again before moving to decision point 130.

In one or more embodiments, at operation 120, the carbon-less iodine-containing metal film is exposed to a reductant. In one or more embodiments, the reducing agent can comprise any reductant known to one of skill in the art.

In specific embodiments, the reductant comprises thermal hydrogen (H₂). In other embodiments, the reactant comprises hydrogen (H₂) plasma. In one or more embodiments, the reactant comprises an alcohol having a general formula of R—OH, wherein R is an alkyl group. In some embodiments, the alkyl group, R, has from 1 to 20 carbon atoms, or 1 to 10 carbon atoms, or 1 to 8 carbon atoms. In one or more embodiments, as an example, the general formula of R—OH includes methanol, ethanol, propanol, butanol, pentanol, hexanol, heptanol, and octanol. In one or more embodiments, the general formula of R—OH includes one or more of primary, secondary, and tertiary alcohols. In one or more embodiments, the reactant comprises thermal ammonia (NH₃). In one or more embodiments, the reactant comprises ammonia (NH₃) plasma.

Unless otherwise indicated, the term “lower alkyl,” “alkyl,” or “alk” as used herein alone or as part of another group includes both straight and branched chain hydrocarbons, containing 1 to 20 carbons, or 1 to 10 carbon atoms, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted. In some embodiments, the iodine-containing reactant comprises one or more of the alkyl groups above. In some embodiments, the reductant comprises one or more of the alkyl groups above.

In one or more embodiments, at operation 120, exposure to the reductant forms a high purity metal film. In one or more embodiments, at operation 120, exposure to the reductant removes iodine from metal-iodine bonds to form the deposited film (e.g., the metal film). In one or more embodiments, at operation 120, exposure to the reductant converts Mo—I bonds, W—I bonds, Os—I bonds, Red bonds, Ir—I bonds, Ni—I bonds, and Ru—I bonds to molybdenum (Mo), tungsten (W), osmium (Os), rhenium (Re), iridium (Ir), nickel (Ni), and ruthenium (Ru), respectively.

In one or more embodiments, at operation 120, exposure to the reductant decreases a resistivity of the carbon-less iodine-containing metal film by an amount greater than or equal to 50%.

In one or more embodiments, at operation 120, exposure to the reductant increases a density of the metal film as compared to a density of a metal film not exposed to a reductant. In one or more embodiments, the metal film that has been exposed to a reductant has a density in a range of 7 mg/m³ to 10.2 mg/m³. In one or more embodiments, the metal film that has not been exposed to a reductant has a density lower than the density of a comparable film with exposure to the reductant.

The period of time of each operation in deposition 110 can be varied in order to form a deposited film (e.g., the metal film) of a predetermined thickness. In one or more embodiments, at operation 112, the method 100 comprises exposing the substrate (or substrate surface) to an organometallic precursor for 1 second. In one or more embodiments, at operation 114, the method 100 optionally includes purging the substrate for 2 seconds. In one or more embodiments, at operation 116, the method 100 comprises exposing the substrate to the iodine-containing reactant for 1 second. In one or more embodiments, at operation 118, the method 100 optionally includes purging the substrate for 10 seconds. In one or more embodiments, the method 100, at operation 120, further comprises exposing the carbon-less iodine-containing metal film to a reductant for a time in the range of 1 second to 120 seconds. In one or more, the method 100 includes exposing the carbon-less iodine-containing metal film to the reductant at a pressure in the range of 2 Torr to 50 Torr. In one or more embodiments, the method 100 optionally includes, after exposing the carbon-less iodine-containing film to the reductant (not shown), purging the substrate for 10 seconds.

In an un-illustrated embodiment, the method 100 further comprises exposing the metal film to plasma treatment. In one or more embodiments, plasma treatment with inert or reactive gases is found to be effective. In one or more embodiments, the plasma treatment is generated by a remote plasma source (RPS) or a capacitively coupled plasma (CCP) or an inductively coupled plasma (ICP) with ambient like argon (Ar), helium (He), ammonia (NH₃), nitrogen (N₂), hydrogen (H₂), or their mixtures.

At decision 130, the thickness of the deposited film, or number of cycles of organometallic precursor, iodine-containing reactant, and reductant is considered. If the deposited film has reached a predetermined thickness or a predetermined number of process cycles have been performed, the method 100 moves to an optional post-processing operation 130. If the thickness of the deposited film or the number of process cycles has not reached the predetermined threshold, the method 100 returns to operation 110 to expose the substrate surface to the organometallic precursor again in operation 112 and continues processing.

In one or more embodiments, the deposited film (e.g., the metal film) has a thickness in a range of from 10 Å to 500 Å, or 20 Å to 450 Å, or 30 Å to 400 Å.

In one or more embodiments, the deposited film (e.g., the metal film) has a resistivity less than or equal to 100 μΩ-cm. In one or more embodiments, the deposited film (e.g., the metal film) has a resistivity less than or equal to 75 μΩ-cm, less than or equal to 50 μΩ-cm, less than or equal to 25 μΩ-cm, less than or equal to 20 μΩ-cm, less than or equal to 15 μΩ-cm, less than or equal to 10 μΩ-cm, or less than or equal to 5 μΩ-cm.

The optional post-processing operation 140 can be, for example, a process to modify film properties (e.g., annealing) or a further film deposition process (e.g., additional ALD or CVD processes) to grow additional films. In some embodiments, the optional post-processing operation 140 can be a process that modifies a property of the deposited film. In some embodiments, the optional post-processing operation 140 comprises annealing the as-deposited film. In some embodiments, annealing is done at temperatures in the range of 300° C. to 500° C. The annealing environment of some embodiments comprises an inert gas (e.g., argon (Ar)) and a reducing gas (e.g., molecular hydrogen (H₂)). In one or more embodiments, the optional post-processing operation 140 comprises flowing in a range of from 100 sccm to 5,000 sccm of the inert gas and flowing in a range of from 100 sccm to 10,000 sccm of the reducing gas. Annealing can be performed for any suitable length of time. In some embodiments, the film is annealed for a predetermined time in the range of about 15 seconds to about 45 minutes, or in the range of about 1 minute to about 30 minutes. In some embodiments, the film is annealed for 25 minutes. In some embodiments, annealing the as-deposited film increases the density, decreases the resistivity and/or increases the purity of the film.

The method 100 can be performed at any suitable temperature depending on, for example, the organometallic precursor, iodine-containing reactant, reductant, or thermal budget of the device. In one or more embodiments, the use of high temperature processing may be undesirable for temperature-sensitive substrates, such as logic devices. In some embodiments, exposure to the organometallic precursor (operation 112) and the iodine-containing reactant (operation 116) occur at the same temperature as exposing the carbon-less iodine-containing metal film to a reductant (operation 120). In some embodiments, the substrate is maintained at a temperature in a range of 150° C. to about 500° C.

In one or more embodiments, the deposition operation 110 can be repeated to form a film having a predetermined thickness.

In some embodiments, exposure to the organometallic precursor (operation 112) and the iodine-containing reactant (operation 116) occurs at a different temperature than exposing the carbon-less iodine-containing metal film to a reductant (operation 120). In one or more embodiments, the substrate surface is exposed to the organometallic precursor (operation 112) and the iodine-containing reactant (operation 116) at a first temperature and to the reductant (operation 120) at a second temperature different from the first temperature. In one or more embodiments, the first temperature is in a range from 150° C. to 500° C., for the exposure to the organometallic precursor (operation 112) and the iodine-containing reactant (operation 116) and the second temperature is in a range from 300° C. to 500° C., for the exposure to the reductant.

In the embodiment illustrated in FIG. 1, at deposition operation 110 the substrate (or substrate surface) is exposed to the organometallic precursor, the iodine-reactant, and the reductant sequentially. In another, un-illustrated, embodiment, the substrate (or substrate surface) is exposed to the organometallic precursor, the iodine-containing reactant, and the reductant simultaneously in a CVD reaction. In a CVD reaction, the substrate (or substrate surface) can be exposed to a gaseous mixture of the organometallic precursor and iodine-containing reactant to deposit a carbon-less iodine-containing film. The carbon-less iodine-containing film is exposed to a reductant to form the deposited film (e.g., the metal film). In the CVD reaction, the deposited film (e.g., the metal film) can be deposited in one exposure to the mixed reactive gas or can be multiple exposures to the mixed reactive gas with purges between.

Some embodiments of the disclosure provide methods for depositing a high purity metal film. The methods of various embodiments use atomic layer deposition (ALD) to provide pure or nearly pure metal films. While exemplary embodiments of this disclosure refer to the deposition of molybdenum, it is conceived that the principles of this disclosure enable the deposition of highly pure metal films regardless of which metal selected from the group consisting of molybdenum (Mo), tungsten (W), osmium (Os), rhenium (Re), iridium (Ir), nickel (Ni) and ruthenium (Ru) is deposited.

Some embodiments of the disclosure provide methods of selectively depositing metal films on a metal surface over a dielectric surface. Some embodiments of the disclosure provide methods of selectively depositing metal films on a dielectric surface over a metal surface. As used in this specification and the appended claims, the term “selectively depositing a film on one surface over another surface”, and the like, means that a first amount of the film is deposited on the first surface and a second amount of film is deposited on the second surface, where the second amount of film is less than the first amount of film, or no film is deposited on the second surface.

The term “over” used in this regard does not imply a physical orientation of one surface on top of another surface, rather a relationship of the thermodynamic or kinetic properties of the chemical reaction with one surface relative to the other surface. For example, selectively depositing a molybdenum film onto a metal surface over a dielectric surface means that the molybdenum film deposits on the metal surface and less or no molybdenum film deposits on the dielectric surface; or that the formation of a molybdenum film on the metal surface is thermodynamically or kinetically favorable relative to the formation of a molybdenum film on the dielectric surface.

The selectivity of a deposition process is generally expressed as a multiple of growth rate. For example, if one surface film is grown (or deposited on) 25 times thicker than a different surface, the process would be described as having a selectivity of 25:1. In this regard, higher ratios indicate more selective processes.

Some embodiments of the disclosure advantageously provide methods for depositing metal films with high purity. Accordingly, these highly pure films exhibit similar properties to their associated bulk metallic materials. For example, some embodiments of this disclosure provide molybdenum films which are smoother and have lower resistance than molybdenum films deposited by conventional oxygen or hydrogen reactant processes. Some embodiments of this disclosure advantageously provide metal films which conformally fill gaps without a seam.

In spatial ALD embodiments, exposure to each of the process gases occurs simultaneously to different parts of the substrate so that one part of the substrate is exposed to the first reactive gas while a different part of the substrate is exposed to the second reactive gas (if only two reactive gases are used). The substrate is moved relative to the gas delivery system so that each point on the substrate is sequentially exposed to both the first and second reactive gases. In any embodiment of a time-domain ALD or spatial ALD process, the sequence may be repeated until a predetermined layer thickness is formed on the substrate surface.

Some embodiments of the disclosure are directed to processes that use a reaction chamber with multiple gas ports that can be used for introduction of different chemicals or plasma gases. Spatially, these gas ports (also referred to as channels) are separated by inert purging gases and/or vacuum pumping holes to create a gas curtain that minimizes or eliminates mixing of gases from different gas ports to avoid unwanted gas phase reactions. Wafers moving through these different spatially separated ports get sequential and multiple surface exposures to different chemical or plasma environment so that layer by layer film growth in spatial ALD mode or surface etching process occur. In some embodiments, the processing chamber has modular architectures on gas distribution components and each modular component has independent parameter control (e.g., RF or gas flow) to provide flexibility to control, for example, gas flow and/or RF exposure.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

One or more embodiments of the disclosure are directed to methods of depositing metal films in high aspect ratio features. A high aspect ratio feature is a trench, via or pillar having a height:width ratio greater than or equal to about 10, 20, or 50, or more. In some embodiments, the metal film is deposited conformally on the high aspect ratio feature. As used in this manner, a conformal film has a thickness near the top of the feature that is in the range of about 80-120% of the thickness at the bottom of the feature.

Some embodiments of the disclosure advantageously provide for the selective deposition of metal films with high purity on metallic surfaces over dielectric surfaces. For example, selectively depositing molybdenum on copper over dielectrics advantageously provides copper capping layers without additional etch or lithography steps.

Some embodiments of the disclosure advantageously provide for the selective deposition of metal films with high purity on dielectric surfaces over metallic surfaces. For example, selectively depositing metals over dielectrics advantageously provides metal layers on barriers or other dielectrics in back end applications.

The purity of the metal film is high. In some embodiments, the metal film has a carbon content less than or equal to 20%, including less than or equal to 15%, less than or equal to 10%, less than or equal to 9%, less than or equal to 8%, less than or equal to 7%, less than or equal to 6%, less than or equal to 5%, less than or equal to 4%, less than or equal to 3%, less than or equal to 2%, less than or equal to 1%, or less than or equal to 0.5% carbon, on an atomic basis. In some embodiments, the metal film has a purity of greater than or equal to 90%, greater than or equal to 95%, greater than or equal to 97%, greater than or equal to 99%, greater than or equal to 99.5%, or greater than or equal to 99.9% metal atoms on an atomic basis.

Some embodiments of the disclosure advantageously provide methods of depositing conformal metal films on substrates comprising high aspect ratio structures. As used in this regard, the term “conformal” means that the thickness of the metal film is uniform across the substrate surface. As used in this specification and the appended claims, the term “substantially conformal” means that the thickness of the metal film does not vary by more than about 10%, 5%, 2%, 1%, or 0.5% relative to the average thickness of the film. Stated differently a film which is substantially conformal has a conformality of greater than about 90%, 95%, 98%, 99% or 99.5%.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A method of depositing a film, the method consisting essentially of:
exposing a substrate surface to an organometallic precursor comprising metal-carbon bonds and an iodine-containing reactant, the iodine-containing reactant converting the metal-carbon bonds to metal-iodine bonds to form a carbon-less iodine-containing metal film; and
exposing the carbon-less iodine-containing metal film to a reductant to convert the metal-iodine bonds to a metal and form a metal film having a resistivity less than or equal to 15 μΩ-cm.

2. The method of claim 1, wherein the organometallic precursor comprises a metal selected from the group consisting of molybdenum (Mo), tungsten (W), osmium (Os), rhenium (Re), iridium (Ir), nickel (Ni) and ruthenium (Ru).

3. The method of claim 2, wherein the organometallic precursor comprises molybdenum (Mo).

4. (canceled)

5. The method of claim 1, wherein the iodine-containing reactant comprises a species having a formula Rh, where R is one or more of a C₁-C₁₀ alkyl, cycloalkyl, alkenyl, or alkynyl group and x is in a range of 1 to 4.

6. The method of claim 5, wherein the iodine-containing reactant comprises diiodomethane (CH₂I₂).

7. The method of claim 1, wherein the substrate surface is exposed to the organometallic precursor and the iodine-containing reactant sequentially.

8. The method of claim 7, wherein the substrate surface is exposed to the iodine-containing reactant prior to exposure to the organometallic precursor.

9. (canceled)

10. The method of claim 1, wherein the reductant comprises H₂ or hydrogen plasma.

11. The method of claim 10, wherein the metal film has a carbon content less than or equal to 20 atomic percent.

12. The method of claim 10, wherein the metal film has an oxygen content less than or equal to 10 atomic percent.

13. The method of claim 10, wherein the metal film has a resistivity less than or equal to 100 μΩ-cm.

14. The method of claim 10, wherein the substrate surface is maintained at a temperature in a range of 150° C. to 500° C.

15. The method of claim 14, wherein the substrate surface is exposed to the organometallic precursor and the iodine-containing reactant at a first temperature and to the reductant at a second temperature different from the first temperature.

16. The method of claim 15, wherein the first temperature is in a range from 150° C. to 500° C. and the second temperature is in a range from 300° C. to 500° C.

17. The method of claim 1, wherein exposure to the reductant decreases a resistivity of the carbon-less iodine-containing metal film by an amount greater than or equal to 50%.

18. The method of claim 10, wherein the metal film comprises greater than or equal to 90% metal species on an atomic basis.

19. A method of depositing a film, the method consisting essentially of:
exposing a substrate surface to an organometallic precursor comprising a metal selected from the group consisting of molybdenum (Mo), tungsten (W), osmium (Os), rhenium (Re), iridium (Ir), nickel (Ni) and ruthenium (Ru), the organometallic precursor comprising Mo—C bonds, W—C bonds, Os—C bonds, Re—C bonds, Ir—C bonds, Ni—C bonds, or Ru—C bonds and an iodine-containing reactant comprising a species having a formula Rh, where R is one or more of a C₁-C₁₀ alkyl, cycloalkyl, alkenyl, or alkynyl group and x is in a range of 1 to 4, the iodine-containing reactant converting the Mo—C bonds, W—C bonds, Os—C bonds, Re—C bonds, Ir—C bonds, Ni—C bonds, or Ru—C bonds to Mo—I bonds, W—I bonds, Os—I bonds, Re—I bonds, Ir—I bonds, Ni—I bonds, or Ru—I bonds to form a carbon-less iodine-containing metal film; and
exposing the iodine-containing metal film to a reductant to convert the Mo—I bonds, W—I bonds, Os—I bonds, Re—I bonds, Ir—I bonds, Ni—I bonds, or Ru—I bonds to molybdenum (Mo), tungsten (W), osmium (Os), rhenium (Re), iridium (Ir), nickel (Ni) or ruthenium (Ru) and form a metal film having a resistivity less than or equal to 15 μΩ-cm.

20. A method of depositing a film, the method consisting essentially of:
exposing a substrate surface to an organometallic precursor comprising molybdenum (Mo) and Mo—C bonds and an iodine-containing reactant comprising diiodomethane (CH₂I₂), the iodine-containing reactant converting the Mo—C bonds to Mo—I bonds to form a carbon-less iodine-containing metal film; and
exposing the carbon-less iodine-containing metal film to a reductant comprising hydrogen (H₂) to convert the Mo—I bonds to molybdenum (Mo) and form a metal film,
wherein the metal film comprises greater than or equal to 90% metal species on an atomic basis, and
wherein the metal film has a resistivity less than or equal to 15 μΩ-cm.

21. The method of claim 19, wherein the reductant comprises one or more of H₂, hydrogen plasma, or an alcohol having a general formula of R—OH, wherein R is an alkyl group having in a range of from 1 to 20 carbon atoms.

22. The method of claim 20, wherein the organometallic precursor comprising molybdenum (Mo) comprises a precursor selected from the group consisting of bis(ethylbenzene)Mo, bis(benzene)Mo, bis(methylbenzene)Mo, (Bicyclo[2.2.1]hepta-2,5-diene)tetracarbonylmolybdenum(0), Cycloheptatriene molybdenum tricarbonyl, (ethylcyclopentadienyl)Mo(NMe₂)₃, (methylcyclopentadienyl)Mo(NMe₂)₃ tBuDADMo(CO)₄, bis(t-butylimido) bis(dimethylamino)Mo, Bis(ethylcyclopentadienyl)Mo dihydride, Mo₁₄, CpMo(CO)₂(NO), and MeCpMo(CO)₂(NO).
